(19) United States
(12) Patent Application Publication
(10) Pub. No.: US 2011/0151198 A1
(43) Pub. Date: Jun. 23, 2011

(54) Micro-Channel Chip and Manufacturing Method and Micro-Channel Chip

(76) Inventors: Takashi Washizu, Tokyo (JP); Hiroshi Hirayama, Tokyo (JP)

(21) Appl. No.: 13/059,359

(22) PCT Filed: Aug. 10, 2009
(86) PCT No.: PCT/JP2009/064121

§ 371 Date: Feb. 16, 2011

(30) Foreign Application Priority Data
Aug. 21, 2008 (JP) 2008-212826

(51) Int. Cl. B81B 1/00; B32B 37/02; B32B 37/06; B32B 37/10; B32B 3/30

(52) U.S. Cl. 428/172; 156/196

(57) ABSTRACT

A micro-channel chip is produced while preventing a resinous film from sagging into the channel. The chip hence inhibits a liquid specimen from residing therein. With the chip, quantitativeness and reproducibility are heightened. A process for producing a micro-channel chip is provided which comprises bonding a resinous film 020 to that side of a resinous substrate 010 which has channel grooves 011 formed. The deflection temperature under load of the resinous substrate 010 Ts (.degree. C), and the deflection temperature under load of the resinous film 020, Tf (degree. C), satisfy Ts>Tf The process includes a pressing stage in which the resinous substrate 010 and the resinous film 020 are press-bonded at a bonding temperature, T (.degree. C), satisfying Tf−5 (.degree. C)<T<Tf+5 (.degree. C) and at a pressing pressure in the range of 10-60 kgf/cm2.

### TECHNICAL FIELD

The present invention relates to a micro-channel chip manufacturing method of a micro-channel chip having a micro-channel formed by a micro forming technology and a micro-channel chip manufactured by the method thereof

### BACKGROUND

There are practically used devices so called a micro analysis chip, a micro-channel chip or a μTAS(Micro Total Analysis System) in which a micro-channel and a circuitry are formed by forming a micro-channel groove on a silicon or a glass substrate via a micro technology and by bonding a sealing member in a shape of a flat plate on the substrate so as to perform chemical reaction, separation and analysis of liquid specimens such as nucleic acid, protein and blood in a micro space (hereinafter called micro-channel chip). As a merit of the micro-channel chip, it is considered that there is realized a space saving, portable and economical system which reduces amounts of sample and reagent used and an emission amount of waste liquid.

Also, due to a cost cutting demand of manufacturing, manufacturing of a micro-channel chip having a resinous substrate and a sealing member is being studied.

As methods to bond the resinous substrate and the resinous film there are know bonding methods such as a method to use adhesive, a method to resolve a surface of the resin by a solvent, a method to utilize ultrasonic and a method to use laser fusion bonding and a method to use thermal fusion bonding. However, in case a channel is formed by bonding a tabular sealing member with the resinous substrate, even occurrence of minor distortions and bending of the resinous substrate and the sealing member makes forming of uniform channels difficult which is a problem for the micro-channel chip requiring a high accuracy.

Then, a micro-channel chip configured by bonding a resinous film onto the resinous substrate in which the micro-channel is formed is studied. The aforesaid micro-channel chip is configured with a resinous substrate, in which a channel groove is formed on the surface thereof; and a through hole (the hole through which the reagent is charged and discharged) is formed at ends of the channel groove, and the resinous film bonded on the surface of the resinous substrate.

As methods to bond the resinous substrate and the resinous film, in same manner as the case of the micro-channel chip configured with the aforesaid resinous substrate and the tabular sealing member, there are cited a method to used the adhesive, the method to resolve the surface of the resin by the solvent for bonding and a method to use ultrasonic fusion bonding, a method to used laser fusion bonding, and a method to utilize thermal fusion bonding via a tabular or a roller-shaped pressure device. Among the above methods, the thermal fusion bonding is suitable as the bonding method for mass production because it can be conducted at low cost.

As such micro-channel chip, there is suggested a micro-channel chip wherein an acrylic family resinous film is bonded onto an acrylic resinous substrate such as a polymethyl methacrylate substrate via pressure thermal fusion bonding (refer to Patent Document 1: Unexamined Japanese Patent Application Publication No 2000-319613).

### PRIOR ART

### Patent Document

Patent Document 1: Unexamined Japanese Patent Application Publication No 2000-319613.

### DISCLOSURE OF THE INVENTION

### Problems to be Solved by the Invention

However, in case the micro-channel chip is manufactured using the technology disclosed in the Patent Document 1 (pressure thermal fusion bonding under the conditions of a pressure of 1 kgf/cm², at 104° C. Refer to the exemplary embodiment), it was found that the resinous film was distorted and moved into the through hole and the micro-channel or deformation of the resinous substrate causes deformation of the channel. Also, it is found that the above deformation of the channel is caused by that the resinous film softened by excessive heat is pushed into a space of the channel or the through hole by a pressure, or a vicinity of the bonding surface is distorted by pressing the softened substrate.

As above, in case the deformation of the channel occurs, the micro-channel formed by the channel groove and the resinous film becomes narrower than a prospected cross-sectional shape (rectangle or trapezium), and a flow speed of liquid specimen in an entire channel is reduced or fluctuated, whereby an accurate analysis becomes difficult. Also, in case the resinous film is distorted towards the channel side, an angle formed by the resinous film and a wall of the channel becomes narrower than a prospective angle of 90°, whereby the flow speed of the specimen is partially reduced and variation of the speed occurs, further the distorted resinous film diffuses detection light and as a result, a problem that a detection peak is weaken and the accurate analysis is difficult occurs. At the same time, in case the substrate is distorted, variation of the speed and diffusion of the detection light occur, thus there was a problem that the accurate analysis is difficult.

In the through hole representing an inlet port of the liquid specimen, in case the resinous film is distorted and enters into the through hole or a distortion of the substrate occurs, as a volume the through hole varies, a height of a liquid surface of the liquid specimen filling the through hole varies. Since the volume of the through hole is extremely greater than that of the channel in comparison, variation of the volume of the through hole affects the flow speed and a direction of the liquid specimen greatly, and analysis may not be earned out, depending on the flow speed and the direction of the liquid specimen. A large variation of the volume of the liquid specimen, in other words poor quantitativeness of the liquid specimen is a serious problem to analyze the liquid specimen. Also, if a water head difference of the liquid specimen between a through hole and other through hole occurs, a flow of the liquid specimen is caused by the water head difference, whereby, a problem that reproducibility was deteriorated also occurred.

In view of the above problems, one of the objects of the present invention is to provide the manufacturing method of the micro-channel chip and the micro-channel chip obtained by the method thereof, wherein in the micro-channel chip, the distortion of the channel is suppressed, accumulation of the liquid specimen is suppressed, quantitativeness and reproducibility are enhanced and a sufficient bonding force between the resinous substrate and the resinous film is obtained.

### Means to Resolved the Problem

The above object is achieved by the following.

Item 1. A micro-channel chip manufacturing method to bond a resinous film onto a surface of a resinous substrate on which a channel groove is formed, wherein a deflection temperature under load of the resinous substrate Ts CC) and a deflection temperature under load of the resinous film Tf (° C.) satisfy Ts>Tf, including a step of pressing the resinous film onto the resinous substrate with a pressure in the rage of 10 kgf/cm²-60 kgf/cm²under a bonding temperature of T (° C.) which satisfies Tf−5(° C.)<T<Tf+5 (° C.).

As a result of study of the inverters, in case that the relation between the deflection temperature under load of the resinous substrate Ts and the deflection temperature under load of the resinous film Tf does not satisfy that Ts>Tf, it was revealed that a sufficient bonding strength and suppression of the channel deformation as the micro-channel chip are difficult to be achieved. Also, even in case the above relation is satisfied, if the bonding temperature is increased while maintaining conventional pressure so as to enhance the bonding strength, the distortion of the resinous film in the channel direction and the deformation of the channel due to deformation of the resinous substrate occur. Thus it was revealed that sufficient analysis accuracy is difficult to be maintained. Also, in case the temperature was adjusted while maintaining the conventional pressure, if the temperature was decreased, a sufficient bonding strength cannot be obtained and if the temperature was increased, the channel deformation also occurred and it was difficult to maintain the analysis accuracy.

Also, as a result of further study of the inventers, it became possible to sufficiently suppress the deformation by carrying out bonding under a far lower bonding temperature than a conventional temperature and a far higher pressure than a conventional temperature, in case the deflection temperature under load of the resinous substrate Is and the deflection temperature under load Tf of the resinous film satisfied the relation that Ts>Tf, and it was revealed that a sufficient bonding force can be obtained. In the above configuration, reduction and variation of the cross-sectional of the channel can be suppressed. Further, deterioration of reproducibility of detection can be obviated.

Item 2. The micro-channel chip manufacturing method of item 1, wherein the pressing step includes: a first pressing step to press the resinous film onto the resinous substrate with a pressure of more than 10 kgf/cm² and not more than 60 kgf/cm², and a second pressing step to press the resinous film onto the resinous substrate with a pressure smaller than the that of the first pressing step.

According to the configuration of item 2, by carrying out bonding the resinous substrate and the resinous film with the first pressing state and the second pressing stage where bonding is carried out with a smaller pressure than that of the first stage, the deformation of the channel is further suppressed and an effect to increase the bonding temperature is obtained.

Item 3. The micro-channel chip manufacturing method of item 1, wherein the pressing step includes: a first pressing step to press the resinous film onto the resinous substrate with a pressure of more than 30 kgf/cm² and not more than 60 kgf/cm², and a second pressing step to press the resinous film onto the resinous substrate with a pressure in the rage of 10 kgf/cm 2-30 kgf/cm²

According to the configuration of item 3, the deformation of the channel can be further suppressed and an effect to increase the boding strength can be obtained by setting the pressure of the first pressing stage in the range of 30 kgf/cm² to 60 kgf/cm² and the pressure of the second pressing stage in the 10 kgf/cm² to 30 kgf/cm².

Item 4. The micro-channel chip manufacturing method of item 2 or 3, wherein a pressing time of the fist pressing step is shorter than a pressing time of the second pressing step.

According to the configuration of item 4, the deformation of the channel is further suppressed and an effect to enhance the bonding strength can be obtained by making the application time of the pressure shorter in the first pressing stage than that in the second pressing stage.

Item 5. The micro-channel chip manufacturing method of any one of items 1 to 4, further including a step of applying thermal annealing to the resinous substrate and the resinous film before the pressing step.

According to the configuration of item 5, the resinous film contracts via thermal annealing and an effect to suppress deformation due to distortion of the resinous film occurred at bonding by adding a stage to carry out thermal annealing with respect to the resinous substrate and the resinous film after pressing stages.

Item 6. A micro-channel chip manufactured by the micro-channel chip manufacturing method of any one of items 1 to 5.

### Effect of the Invention

According to the micro-channel chip manufacturing method related to the present invention, the deformation of the micro-channel is suppressed by reducing distortion of the resinous film and the deformation of the resinous substrate in the micro-channel chip to be manufactured, and the sufficient bonding force can be obtained. Whereby, the quantitativeness and the reproducibility are enhanced in the micro-channel chip manufactured using the micro-channel manufacturing method related to the present invention, namely the micro-channel chip related to the present invention.

### BRIEF DESCRIPTION OF DRAWINGS

FIG. 1 is a diagram explaining a resinous substrate used in a micro-channel chip manufacturing method related to an embodiment of the present invention.

FIG. 2 is a cross-sectional view of a micro-channel chip.

FIG. 3 is a table describing conditions and results of examples and comparison examples in a first embodiment and a second embodiment.

FIG. 4 is a table describing conditions and results of examples and comparison examples in a third embodiment.

### DESCRIPTION OF THE PREFERRED EMBODIMENTS

### First Embodiment

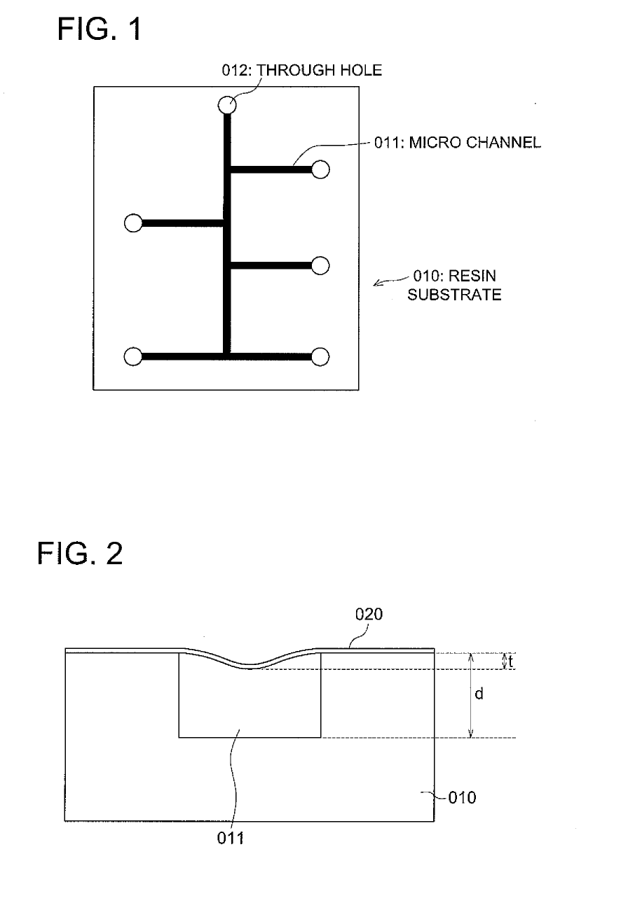

The manufacturing method of the micro-channel chip related to the first embodiment will be described as follow. FIG. 1 is a diagram explaining a resinous substrate used in the micro-channel chip manufacturing method related to the embodiment of the present invention. FIG. 2 is a cross-sectional view of the micro-channel chip.

The resinous substrate 010 shown by FIG. 1 is provided with a plurality of through holes 012. Further, the resinous substrate 010 is provided with a micro-channel by which the plurality of the through holes are connected one another.

As the material of the resinous substrate 010 a resin is used. As conditions of the resin, there are cited preferable formability (transferability and releasability), high transparency, and low self-fluorescence with respect to the ultraviolet ray and visible ray, while the resin is not restricted by the conditions thereof For example, acrylic family resins such as polymethylmethaerylate, polyaerylate, styrene family resins such as polystyrene, styrene copolymer, and polycarbonate, nylon 6, nylon 66, and polyethylene terephthalate are preferable.

In the present invention, the deflection temperature under load of the resinous substrate 010 is described as Ts (° C.). Here, the deflection temperature under load of the resinous substrate 010 Ts is (° C.) describes the deflection temperature under load of the material configuring the resinous substrate and in particular a value obtained via a flat wise test (A method) defined by a test method JIS K 7 191:2007.

The size and shape of the resinous substrate 010 can be discretional as far as they facilitate handling and analysis. For example, 10 mm square to 150 mm square is preferable, and 20 mm square to 100 mm square is more preferable. The shape of the resinous substrate 010 has only to be adaptable for the analysis method and the analysis apparatus, thus a square shape, a rectangular shape and a round shape are preferred.

Further, while the forming method of the resinous substrate 010 is not limited, for example, shot molding, injection molding, and press forming using a metal mold as well as machining are cited.

The shape of the micro-channel 011 is preferred to be 10 μm to 200 μm in a width and a depth without being limited in view of saving the amount used of analysis specimen and reagent, forming accuracy, transferring characteristic and mold releasability of the metal mold. Also, an aspect ratio (a ratio of depth and width of the channel) is preferred to be 0.1 to 3 and more preferably 0.2 to 2. Also, the width and the depth of the micro-channel 011 can be decided in accordance with use of the micro-channel chip.

Also, the thickness of the resinous substrate 010 is decided so as to have only to facilitate molding and handling. For example, a thickness of 0.2 mm to 5 mm is preferred and 1 mm to 2 mm is more preferred.

The resinous film 020 is a resin material in a film shape. In the present embodiment, the deflection temperature under load of the resinous film 020 is described as Tf (° C.). Here, the deflection temperature under load Tf (° C.) of the resinous film 020 describes the deflection temperature under load of the material configuring the resinous film 020 and in the same manner as the deflection temperature under load Tc (° C.) of the resinous substrate 010, a value thereof is measured via a flat wise test (A method) defined by a test method JIS K 7191:2007. In the present invention, it is necessary to satisfy that Ts (deflection temperature under load of the resinous substrate)>Tf (deflection temperature under load of the resinous film). While the material of the resinous film 020 is not limited as far as it satisfies the above relation, used of any of the aforesaid materials cited for the resinous substrate 010 is preferred. Also it is preferred that the resinous film 020 has the same surface shape as that of the resinous substrate 010 so as to be bonded with the resinous substrate 010.

In view of formability and adhesiveness, the thickness of the resinous film 020 is preferred to be a value within the range of 50 μm to 200 μm without being limited.

Next, bonding of the resinous substrate 010 and the resinous film 020 will be specifically described. Bonding is carried out using a press machine. In the press machine, two platens are disposed in opposite positions so that the two platens are disposed in a movable manner in a direction to approach to and recede from one another, and the two platens are able to come close until objects placed on the platens can contact each other.

The resinous substrate 010 is placed on one platen. Then the resinous film 0 is placed on another platen. After that by increasing a temperature in a box storing the resinous substrate 010 and the resinous film 020, a temperature T (° C.) of the resinous substrate 010 and the resinous film 020 is increased up to Tf−5 (° C.)<T<Tf+5(° C.). The above temperature T represents a “bonding temperature T”. In the present embodiment, the material is selected so that the deflection. temperature under load Tf of the resinous film 020 is higher than the deflection temperature under load Ts of the resinous substrate 010, and further the bonding temperature is closed to the deflection temperature under load of the resinous film 020. By setting the above conditions, the distortion of the resinous substrate 010 does not occur even a high pressure is applied, and the distortion of the resinous film 020 in the channel direction can be suppressed. Here, even in case the bonding temperature is lower than the deflection temperature under load Tf of the resinous film 020, bonding is possible if it is higher than Tf −5 (° C.).

By relatively moving the two platens toward the opposite platen to make the resinous substrate 010 contact with the resinous film 020, and pressure is applied for bonding. A value of the pressure is within the range of 10 kgf/cm² to 60 kgf/cm². The above pressure is applied for 30 sec in the state where the resinous substrate 010 and the resinous film 020 are in contact. The above time is hereinafter called “bonding time”. Here in the present embodiment, the bonding time is 30 sec from experience under the pressure and temperature of the present embodiment so as to sufficiently bond the resinous substrate 010 and the resinous film 020. The bonding time is not limited to the above time as far as the resinous substrate 010 and the resinous film 020 are bonded completely within the time (namely the time in which the heat propagates to a backside of the resinous film 020 and the entire resinous film 020 is heated).

Here, as FIG. 2 shows, supposing that a ratio of a distortion amount with respect to the channel depth d is described as t/d, the distortion of the resinous film 020 in a bonded state in the micro-channel chip manufactured is preferred to be 0≦t/d<0.1. The reasons are described as follow. A flow speed has to be controlled via voltage drive or pressure drive to flow analysis object in the micro-channel 011 in the micro-channel chip. At that time, it has been revealed through an experiment that a cross-section area of the micro-channel 011 affects the flow speed in the channel. In particular in case of pressure drive, as the cross-section area of the micro-channel 011 reduces, the flow speed reduces. It would not be a problem if the same shape is maintained, however in case amounts of the distortion vary among the micro-channel chips, the flow speeds vary and the reproducibility of detection is deteriorated. As results of the experiments of the Inventors, the reproducibility is further enhanced if a relation of the amount of distortion t and the depth d of the micro-channel 011 satisfy 0≦t/d<0.1.

As above, in the micro-channel chip manufacturing method related to the present embodiment, pressing is carried out with a pressure of 10 kgf/cm²-60 kgf/cm², which is higher than that of conventional method. Whereby, bonding of the resinous substrate 010 and the resinous film 020 becomes possible in a lower temperature than that of the conventional method. Since the deflection temperature under load Ts (° C.) of the resinous substrate 010 and the load deflection temperature under load Tf (° C.) of the resinous film 020 satisfy Ts>Tf, and the bonding temperature satisfy Tf−5 (° C.)<T<Tf+5(° C.), deformation of the resinous substrate 010 is suppressed, even in case the rather higher pressure in such level as the present embodiment is applied the distortion of the resinous film 020 is suppressed to be small, thus the deformation of the channel is suppressed almost nil and the reproducibility of detection is improved. Therefore, in the manufacturing method of the micro-channel chip related to the present embodiment, the deformation of the resinous substrate 010 and the distortion of the resinous film 020 are suppressed to be minimum and the variation of deformation of the cross-section area of the channel 011 is suppressed thus the deterioration of reproducibility can be obviated. The variation of the distortion of the resinous film 020 is preferred to be not more than 0.05.

### EMBODIMENTS

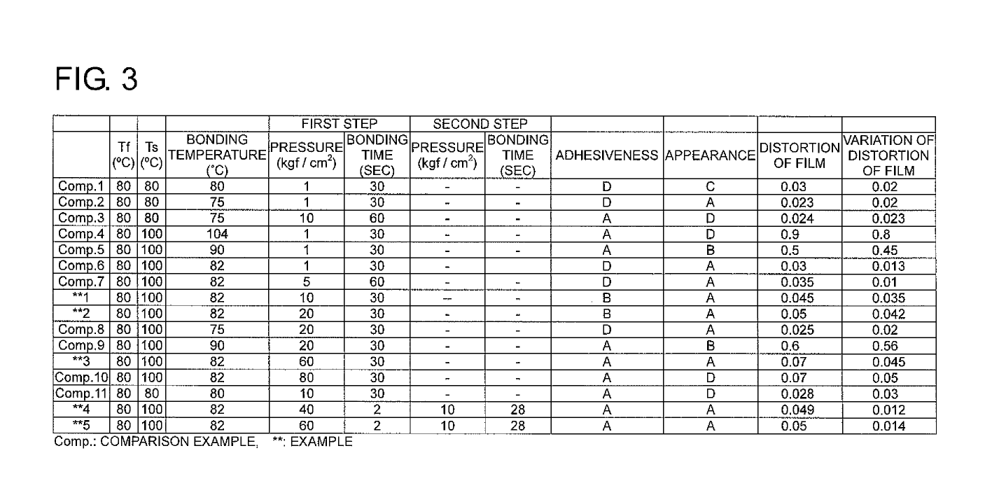

Next, a specific example related to the first embodiment will be described with reference to FIG. 3. FIG. 3 is a table describing conditions and results of examples and comparison examples in a first embodiment and a second embodiment. In each test in FIG. 3, combination of the deflection temperatures under load of the resinous film 020 and the resinous substrate 010, the bonding temperature and the pressure are changed, and the adhesiveness between the resinous film 020 and the resinous substrate 010 (namely degree of uplift of the resinous film), the deformation of the substrate, the distortion of the resinous film 020 and the variation of the distortion of the resinous film 020 (namely a standard variation of the distorted portion) were obtained. Here, the distortion amount t of the resinous film 020 was obtained in a way that assigning a plurality of points at the micro-channel 011 and the through holes 012, and calculating the distortion (t/d) of each point, an average of the resinous film 020 was obtained. Also, As to the variation of the distortions of the resinous film 020, assigning a plurality of points at the micro-channel 011 and the through holes 012, a standard variation is obtained.

In each example and comparison example in FIG. 3, as a resinous substrate 010 having the deflection temperature under load Ts (° C.) of 80° C., a resinous substrate produced by melting Acryplane™ (Acrylic family) of Mitsubishi Rayon Co., Ltd. by heat was used Also, as a resinous substrate 010 having the deflection temperature under load Ts (° C.) of 100° C., a resinous substrate produced by melting Acrypet VH™ (Acrylic family resin) of Mitsubishi Rayon Co., Ltd. by heat was used. Also, as the resinous film 020 Acryplane 75 μm™ (Acrylic family resin) of Mitsubishi Rayon Co, Ltd. was used. The deflection temperature under load Tf (° C.) of the above resinous film is 80° C. In each example and comparison example, a digital press machine of Shinntou industry Co., Ltd. is used for bonding.

### (Measuring Method of Adhesiveness)

Next, a measuring method of adhesiveness will be described. For measuring the adhesiveness, a fluorescence microscope BX51 of Olympus Corporation was used to investigate lift up of the resinous film 020. In FIG. 3 there are four criterion i.e. symbol D denotes that a defect such as lift up of the film occurs, symbol C denotes that though a defect such as lift up of the film occurs, it is improved from D, symbol B denotes that almost no lift up occurs and not tangible harm and symbol A denotes that lift up does not occur at all.

### (Measuring of Appearance)

Next, a measuring method of the appearance will be described. The appearance means whether or not an entire distortion of the micro-channel chip such as the deformation of the substrate exists. In FIG. 3, to evaluate the appearance, the deformation of the resinous substrate 010 is observed with a microscope of Olympus Corporation. Four criterion i.e. symbols D: deformation occurs at the substrate, C: deformation occurs at an edge section of the substrate, B: almost no deformation occurs, and A: no deformation occurs at all are use to evaluate the appearance.

### (Measuring Method of Distortion of the Resinous Film)

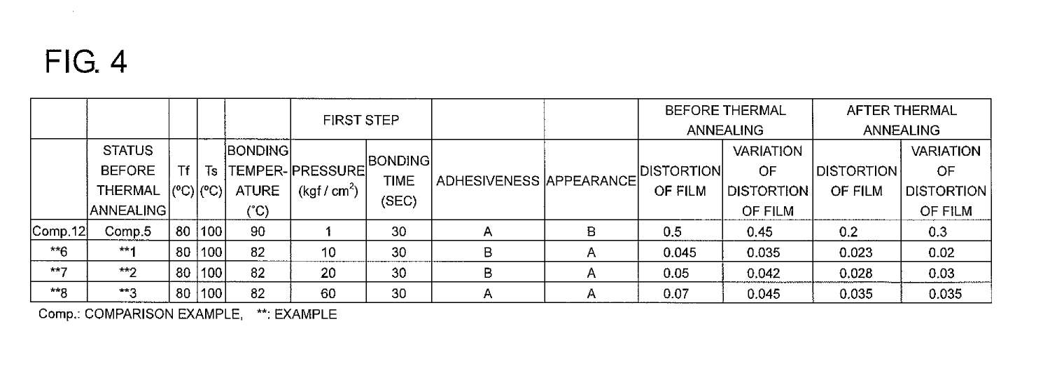

Next, the measuring method of distortion of the resinous film will be described. For the resinous film 020, an optical interference profiler Wyko3300 of Veeco Instruments Inc. was used for measuring distortion of the resinous film 020 in VSI mode. As FIG. 2 shows, the distortion of the resinous film 020 is described as a ratio t/d wherein t is a distortion from the bonding surface toward a bottom of the channel and d is a depth d of the channel. As measurement of the distortion of the resinous film 020, ten positions are selected discretionary at the micro-channel or the through holes and measured, then distortion t/d of each position is calculated and an average is obtained as a distortion amount of the resinous film 020 and a standard variation thereof was defined a variation of the distortion of the resinous film 020. FIG. 4 explains measuring of the distortion of the resinous film 020.

Examples 1, 2 and 3 showing operation conditions and results in FIG. 3 are examples related to the fist embodiment.

### Example 1

In the example 1, the deflection temperature under load Ts (° C.) of the resinous substrate is 100° C., and the deflection temperature under load Tf (° C.) of the resinous film is 80° C. The above deflection temperatures under load satisfy that Ts>Tf. Also, the bonding temperature T (° C.) is 82° C. The above temperature T=Tf+2 satisfies that Tf −5 (° C.)<T<Tf+5 (° C.). Further, the pressure P is 10 kgf/cm² and satisfies that 10 kgf/cm²≦P≦60 kgf/cm². The bonding time is 30 sec.

The results of the present example will be described. As to the adhesiveness, since lift up did not occur, there was no tangible harm. Also, as to the appearance, not deformation occurred, Since the distortion of the resinous film was 0.045 which falls within the range of 0≦t/d<0.1, it is preferable. The variation of the distortion of the resinous film was 0.035. The above variation is not more than 0.05 and it is preferable.

### Example 2

In the example 2, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf Also, the bonding temperature T (° C.) is 82° C. The above temperature T=Tf+2 satisfies that Tf−5 (° C.)<T<Tf+5 (° C.). Further, the pressure P is 20 kgf/cm² and satisfies that 10 kgf/cm²≦P≦60 kgf/cm². The bonding time is 30 sec.

The results of the present example will be described. As to the adhesiveness, since lifting up did not occur, there was no tangible harm. Also, as to the appearance, not deformation occurred at all. Since the distortion of the resinous film 020 was 0.05 which falls within the range of 0≦t/d<0.1, it is preferable. The variation of the distortion of the resinous film 020 was 0.042. The above variation is not more than 0.05 and it is preferable.

### Example 3

In the example 3, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf Also, the bonding temperature T (° C.) is 82° C. The above temperature T=Tf+2 satisfies that Tf−5 (° C.)<T<Tf+5 (° C.). Further, the pressure P is 60 kgf/cm² and satisfies that 10 kgf/cm²≦P≦60 kgf/cm². The bonding time is 30 sec.

The results of the present example will be described. As to the adhesiveness, since lifting up did not occur, there is no tangible harm. Also, as to the appearance, not deformation occurred at all. Since the distortion of the resinous film 020 was 0.07 which falls within the range of 0≦t/d<0.1, it is preferable. The variation of the distortion of the resinous film 020 was 0.045. The above variation is not more than 0.05 and it is preferable.

### Comparison Example 1

In the comparison example 1, the deflection temperature under load Ts (° C.) of the resinous substrate 010 is 80° C., and the deflection temperature under load Tf (° C.) of the resinous film 020 is 80° C. Since the above deflection temperatures under load are Ts=Tf they do not satisfy that Ts>Tf. Also, the bonding temperature T (° C.) is 80° C. The above temperature T=Tf+2 satisfies Tf−5 (° C.)<T<Tf+5 (° C.). Further, the pressure P is 1 kgf/cm² and does not satisfy that 10 kgf/cm²≦P≦60 kgf/cm². The bonding time is 30 sec. Therefore, the comparison example 1 is a case that the relation of the deflection temperature under load and the pressure P do not satisfy configuration requirements of the present invention.

The results of the present example will be described. As to the adhesiveness, bonding failure such as lift up occurred. Also, as to the appearance, deformation occurred at the edge section of the substrate. Since the distortion of the resinous film 020 was 0.03 which falls within the range of 0≦t/d<0.1. The variation of the distortion of the resinous film 020 was 0.02. In case of the present comparison example, since the resinous substrate 010 was deformed, an accurate measuring is difficult.

### Comparison Example 2

In the comparison example 2, the deflection temperature under load Ts (° C.) of the resinous substrate 010 is 80° C., and the deflection temperature under load Tf(° C.) of the resinous film 020 is 80° C. Since the above deflection temperatures under load are Ts=Tf, they do not satisfy that Ts>Tf. Also, the bonding temperature T (° C.) is 75° C. The above temperature does not satisfy Tf−5 (° C.)<T<Tf+5 (° C.). Further, the pressure P is 1 kgf/cm² and does not satisfy that 10 kgf/cm². The bonding time is 60 sec. Therefore, the comparison example 2 is a case that the relation of the deflection temperature under load, bonding temperature T and pressure P do not satisfy configuration requirements of the present invention.

The results of the present example will be described. As to the adhesiveness, a bonding failure such as lift up occurred. Also, as to the appearance, no deformation occurred at all at the substrate. The distortion of the resinous film 020 was 0.023 which falls within the range of 0≦t/d<0.1. The variation of the distortion of the resinous film 020 was 0.02. In case of the present comparison example, since the resinous substrate 010 was deformed, an accurate measuring is difficult

### Comparison Example 3

In the comparison example 3, the deflection temperature under load Ts (° C.) of the resinous substrate 010 is 80° C., and the deflection temperature under load Tf(° C.) of the resinous film 020 is 80° C. Since the above deflection temperatures under load are Ts=Tf they do not satisfy that Ts>Tf. Also, the bonding temperature T (° C.) is 75° C. The above temperature does not satisfy Tf−5 (° C.)<T<Tf+5 (°C.). Further, the pressure P is 10 kgf/cm² which satisfies that 10 kgf/cm²≦P≦60 kgf/cm². The bonding time is 60 sec. Therefore, the comparison example 3 is a case that the relation of the deflection temperatures under load and the bonding temperature T do not satisfy configuration requirements of the present invention.

The results of the present example are described. As to the adhesiveness, lift up of the film did not occur at all. Also, as to the appearance, deformation occurred at the substrate. The distortion of the resinous film 020 was 0.024 which falls within the range of 0t/d<0.1. The variation of the distortion of the resinous film 020 was 0.023. In case of the present comparison example, since the bonding failure occurred, an accurate measuring is difficult

### Comparison Example 4

In the comparison example 4, the deflection temperature under load Ts (° C.) of the resinous substrate 010 is 80 V, and the deflection temperature under load Tf (° C.) of the resinous film 020 is 80° C. The above deflection temperatures under loads satisfy that Ts>Tf. Also, the bonding temperature T (° C.) is 104° C. The above temperature does not satisfy that Tf−5 (° C.)<T<Tf+5 (° C.). Further, the pressure P is 1 kgf/cm² which does not satisfy that 10 kgf/cm²≦P≦60 kgf/cm². The bonding time is 30 sec. Therefore, the comparison example 4 is a case that the bonding temperature T and the pressure P do not satisfy configuration requirements of the present invention.

The results of the present example will be described. As to the adhesiveness, lift up of the film did not occur at all. Also, as to the appearance, the deformation occurred at the substrate. The distortion of the resinous film 020 was 0.9 which does not fall within the range of 0≦t/d<0.1. The variation of the distortion of the resinous film 020 was 0.8 which exceeds 0.05 and is faulty. In case of the present comparison example, since the resinous substrate 010 was deformed, the resinous film 020 was distorted largely and the variation of the distortion was also large, an accurate measuring is difficult

### Comparison Example 5

In the comparison example 5, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf. Also, the bonding temperature T (° C.) is 90° C. The above temperature does not satisfy that Tf−5 (° C.)<T<Tf+5 (° C.). Further, the pressure P is 1 kgf/cm² which does not satisfy that 10 kgf/cm²≦P≦60 kgf/cm². The bonding time is 30 sec. Therefore, the comparison example 5 is a case that the bonding temperature T and the pressure P do not satisfy configuration requirements of the present invention.

The results of the present example will be described. As to the adhesiveness, lift up of the film did not occur at all. Also, as to the appearance, almost no deformation occurred at the substrate. The distortion of the resinous film 020 was 0.5 which does not fall within the range of 0≦t/d<0.1. The variation of the distortion of the resinous film 020 was 0.45. In case of the present comparison example, since the resinous film 020 distorted largely, an accurate measuring is difficult.

### Comparison Example 6

In the comparison example 6, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf Also, the bonding temperature T (° C.) is 82° C. The above temperature satisfies that Tf−5 (° C.)<T<Tf+5 (° C.). Further, the pressure P is 1 kgf/cm² which does not satisfy that 10 kgf/cm²≦P≦60 kgf/cm². The bonding time is 30 sec. Therefore, the comparison example 6 is a case that only the pressure P does not satisfy configuration requirements of the present invention.

The results of the present example will be described. As to the adhesiveness, a bonding failure such as lifting up of the film occurred. Also, as to the appearance, no deformation occurred at the substrate at all. The distortion of the resinous film 020 was 0.03 which falls within the range of 0≦t/d<0.1. The variation of the distortion of the resinous film 020 was 0.013.

### Comparison Example 7

In the comparison example 7, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf. Also, the bonding temperature T (° C.) is 82° C. The above temperature satisfies that Tf−5 (° C.)<T<Tf+5 (° C.). Further, the pressure P is 5 kgf/cm² which does not satisfy that 10 kgf/cm²≦P≦60 kgf/cm². The bonding time is 60 sec. Therefore, the comparison example 7 is a case that only the pressure P does not satisfy configuration requirements of the present invention.

The results of the present example will be described. As to the adhesiveness, a bonding failure such as lifting up of the film occurred. Also, as to the appearance, no deformation occurred at the substrate at all. The distortion of the resinous film 020 was 0.035 which falls within the range of 0t/d<0.1. The variation of the distortion of the resinous film 020 was 0.01.

The micro-channel chips related to the comparison examples 6 and 7, satisfy the quality as the product except the adhesiveness, however since lifting up of the film occurred, they do not satisfy the quality as the product in the adhesiveness, the accurate analysis is difficult. As above it was revealed that in order to suppress the distortion, a certain pressure is necessary in case of bonding is carried out at a low temperature. Namely, it is revealed that the condition of pressure P of the present invention is a necessary condition.

### Comparison Example 8

In the comparison example 8, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf. Also, the bonding temperature T (° C.) is 75° C. The above temperature is lower than a lower limit of the condition that Tf −5 (° C.)<T<Tf+5 (° C.). Thus the comparison example does not satisfy the conditions. Further, the pressure P is 20 kgf/cm² which satisfies that 10 kgf/cm²≦P≦60 kgf/cm². The bonding time is 30 sec. Therefore, the comparison example 8 is a case that configuration requirements of the present invention are not satisfied, since the bonding temperature T is lower than the lower limit of the condition of the bonding temperature T of the present invention

The results of the present example will be described. As to the adhesiveness, a bonding failure such as lifting up of the film occurred. Also, as to the appearance, no deformation occurred at the substrate at all. The distortion of the resinous film 020 was 0.025 which falls within the range of 0t/d<0.1. The variation of the distortion of the resinous film 020 was 0.02.

The micro-channel chip related to the comparison example satisfies the quality as the product except the adhesiveness, however since lift up of the film occurred, they do not satisfy the quality as the product in the adhesiveness, the accurate analysis is difficult. As above it was revealed that in order to suppress the distortion, the pressure has to be lowered, however to carry out appropriate bonding, a temperature above a certain temperature is necessary. Namely, it is revealed that the condition of the lower limit of the bonding temperature T of the present invention is a necessary condition.

### Comparison Example 9

In the comparison example 9, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf. Also, the bonding temperature T (° C.) is 90° C. The above temperature is higher than an upper limit of the condition that Tf−5 (° C.)<T<Tf+5 (° C.). Thus the comparison example does not satisfy the conditions. Further, the pressure P is 20 kgf/cm² which satisfies that 10 kgf/cm²≦P≦60 kgf/cm². The bonding time is 30 sec. Therefore, the comparison example 9 is a case that configuration requirements of the present invention are not satisfied, since the bonding temperature T is higher than the upper limit of the condition of the bonding temperature T of the present invention

The results of the present example are described. As to the adhesiveness, a bonding failure such as lift up of the film did not occurred at all Also, as to the appearance, almost no deformation occurred at the substrate. The distortion of the resinous film 020 was 0.6 which does not fall within the range of 0≦t/d<0.1. The variation of the distortion of the resinous film 020 was 0.56 which exceeds 0.05 and is faulty.

The micro-channel chip related to the comparison example satisfies the quality such as the adhesiveness and the appearance except results of the distortion and the variation of the distortion, however since the distortion and the variation of the distortion are excessive, the reproducibility is greatly deteriorated. Therefore, it is revealed that in order to carry out appropriate bonding the temperature has to be increased though the temperature has to be below a certain temperature to suppress the distortion and the variation of the distortion. Namely the upper limit of the bonding temperature of the present invention is a necessary condition.

### Comparison Example 10

In the comparison example 10, the deflection temperature under load Ts (° C.) of the resinous substrate 010 is 100° C., and the deflection temperature under load Tf (° C.) of the resinous film 020 is 80° C. The above deflection temperatures under load satisfy that Ts>Tf. Also, the bonding temperature T (° C.) is 82° C. The above temperature satisfies the condition that Tf−5 (° C.)<T<Tf+5 (° C). Further, the pressure P is 80 kgf/cm² which does not satisfy that 10 kgf/cm²≦P≦60 kgf/cm². The bonding time is 30 sec. Therefore, the comparison example 10 is a case that only the pressure P does not satisfy the configuration requirements of the present invention.

The results of the present example will be described. As to the adhesiveness, a bonding failure such as lift up of the film did not occurred at all. Also, as to the appearance, a deformation such as a crack occurred at the resinous substrate 10. The distortion of the resinous film 020 was 0.07 which falls within the range of 0≦t/d<0.1. The variation of the distortion of the resinous film 020 was 0.05.

The micro-channel chip related to the comparison example satisfies the quality as the product except the appearance, however since the deformation occurred at the substrate, the quality as the product is not satisfied and the accurate analysis is difficult to be carried out As above, it is revealed that in order to carry out appropriate bonding a certain pressure P is necessary and to maintain the appearance in a good condition, adjustment of the pressure P is necessary. Namely it is revealed that the condition of the pressure P of the present invention is a necessary condition.

### Comparison Example 11

In the comparison example 11, the deflection temperature under load Ts (° C.) of the resinous substrate 010 is 80° C., and the deflection temperature under load Tf (° C.) of the resinous film 020 is 80° C. The above deflection temperatures under load do not satisfy that Ts>Tf. Also, the bonding temperature T(° C.) is 80° C. The above temperature satisfies the condition that Tf−5 (° C.)<T<Tf+5 (° C.). Further, the pressure P is 10 kgf/cm² which satisfies that 10 kgf/cm²≦P≦60 kgf/cm². The bonding time is 30 sec. Therefore, the comparison example 11 is a case that only the relation between the deflection temperature under load does not satisfy the configuration requirements of the present invention.

The results of the present example are described. As to the adhesiveness, a bonding failure such as lift up of the film did not occurred at all. Also, as to the appearance, a deformation such as a crack occurred at the resinous substrate 10. The distortion of the resinous film 020 was 0.028 which falls within the range of 0t/d<0.1. The variation of the distortion of the resinous film 020 was 0.03.

The micro-channel chip related to the comparison example satisfies the quality as the product except the result of the appearance, however since the deformation occurred at the substrate, the quality as the product is not satisfied and the accurate analysis is difficult to be carried out. As above it is revealed that in order to carry out appropriate bonding, the relation between the deflection temperatures under load has to satisfy that Ts>Tf. Namely it is revealed that the condition of the relation between the deflection temperatures under load of the present invention is a necessary condition.

As above, the quality as the product was satisfied in the items such as the adhesiveness, the appearance, the distortion of the film and the variation of the distortion of the film in the examples 1, 2 and 3 in which the micro-channel chips were manufactured via the micro-channel chip manufacturing method related to the present embodiment. Contrarily, in the comparison examples wherein one of the relation between the deflection temperatures under load, the bonding temperature T, and the pressure P or combinations thereof are different form the condition of the present invention, through some items are in satisfactory states, since at least one item does not satisfy the quality of as the product, it cannot be used. Therefore, in case total performances of the micro-channel chips of examples and the comparison examples are compared, each comparison example is inferior to each example in the performance.

### Second Embodiment

Next, a manufacturing method of the micro-channel chip related to the second embodiment will be described. The manufacturing method of the micro-channel chip related to the present embodiment is different from the first embodiment in a point that the pressure is gradually changed. Thus the pressure will be mainly described in the following.

The configuration of the resinous substrate 010, the configuration of the resinous film 020, the relation between the deflection temperatures under load, and the bonding temperature in the present embodiment are the same as that of the first embodiment.

In the present embodiment, different pressures P having different values are applied in two stages respectively when the resinous substrate 010 and the resinous film 020 are bonded. In the first pressing (“first pressing stage” of the present invention) the resinous film 020 is pressed against the resinous substrate 010 with a pressure P which satisfies 30 kgf/cm²≦P≦60 kgf/cm² in a short time compared to that of the second pressing (“second pressing stage” of the present invention). Then in the second pressing, the resinous film 020 is pressed against the resinous substrate 010 with a pressure P which satisfies 10 kgf/cm²≦P≦30 kgf/cm² in a longer time compared to that of the first pressing.

As above, in the first pressing, by pressing the resinous film 020 against the resinous substrate 010 with the pressure P having a higher value compared with that of the second pressing, the resinous substrate 010 and the resinous film 020 are adhered completely before the distortion occurs. Then in the second pressing, by pressing the resinous film 020 against the resinous substrate 010 with the pressure P having a lower value compared to that of the first pressing while applying heat, bonding of the resinous substrate 010 and resinous film 020 are reinforced while suppressing the distortion.

Next, specific examples related to the second embodiment will be described with reference to the FIG. 3. Examples 4 and 5 showing operation conditions and results in FIG. 3 are examples related to the second embodiment.

### Example 4

In the example 4, the deflection temperature under load Ts (° C.) of the resinous substrate is 100° C., and the deflection temperature under load Tf(° C.) of the resinous film is 80° C. The above deflection temperatures under load satisfy that Ts>Tf. Also, the bonding temperature T (° C.) is 82° C. The above temperature T+Tf+2 satisfies that Tf−5 (° C.)<T<Tf+5 (° C.). Further, the pressure P of the first pressing is 40 kgf/cm²while satisfies that 30 kgf/cm²≦P≦60 kgf/cm². The bonding time is 2 sec. Also, the presser P of the second pressing is 10 kgf/cm² and satisfies that 10 kgf/cm²≦P≦30 kgf/cm². The boding time is 28 sec. Namely the pressing time of the first pressing is shorter that that of the second pressing.

The results of the present example will be described. As to adhesiveness, since lift up of the resinous film 020 did not occur at all. Also, as to the appearance, not deformation occurred at all. The distortion of the resinous film was 0.049 which falls within the range of 0≦t/d<0.1, which is preferable. The variation of the distortion of the resinous film 020 was 0.012. The above variation was not more than 0.05 thus it is preferable.

### Example 5

In the example 5, the deflection temperature under load Ts (° C.) of the resinous substrate is 100° C., and the deflection temperature under load Tf(° C.) of the resinous film is 80° C. The above deflection temperatures under load satisfy that Ts>Tf. Also, the bonding temperature T (° C.) is 82° C. The above temperature T=Tf+2 satisfies that Tf−5 (° C.)<T<Tf+5 (° C.). Further, the pressure P of the first pressing is 60 kgf/cm² while satisfies that 30 kgf/cm²≦P≦60 kgf/cm². The bonding time is 2 sec. Also, the presser P of the second pressing is 10 kgf/cm² and satisfies that 10 kgf/cm²≦P≦30 kgf/cm². The boding time is 28 sec. Namely the pressing time of the first pressing is shorter that that of the second pressing.

The results of the present example will be described. As to adhesiveness, since lift up of the resinous film 020 did not occur at all. Also, as to the appearance, no deformation occurred at all. The distortion of the resinous film was 0.05 which falls within the range of 0≦t/d<0.1, which is preferable. The variation of the distortion of the resinous film 020 was 0.014. The above variation was not more than 0.05 thus it is preferable.

As above, in the examples 4 and 5 representing the examples related to the present embodiment, the adhesiveness, the appearance, the distortion of the film and the variation of the distortion of the film are all in excellent conditions. Further, in case the examples 4 and 5 are compared with the examples 1 and 2, the adhesiveness of the examples 4 and 5 is further enhanced. Also in case the examples 4 and 5 are compared with the examples 3, the variation of the distortion of the films of examples 4 and 5 are further improved.

Namely, in case bonding is carried out by pressing only in the first stage, the distortion of the film and the variation of the distortion of the film can be suppressed however, because of the small pressure, the adhesiveness is rather inferior. Also, in case bonding is carried out only by the pressing in the first stage, the adhesiveness is improved by increasing the pressure force, however since the higher pressure is continuously applied, the distortion of the film and the variation of the distortion of the film are slightly increased. Contrarily, the two stage pressing is carried out while changing the pressure force such as the present embodiment, in the first pressing by pressing with a stranger force in a sort time, the adhesiveness is improved without creating a large distortion, and in the second pressing by pressing with a weak force, bonding is carried out with less distortion. Thus the micro-channel chip having higher reproducibility can be manufactured.

In the present embodiment, while two stage pressing was carried out, there can be configurations having multiple stages to carry out multiple times of pressing. However, in case of a configuration having excessive number of stages, the control becomes complicated and there is possibility that the effect to improve the adhesiveness by the strong force and to suppress the distortion by the weak force is deteriorated. Thus the pressing stages are preferred to be carried out within tree times.

### Third Embodiment

Next, a manufacturing method of the micro-channel chip related to the third embodiment of the present invention will be described The manufacturing method of the micro-channel chip related to the present embodiment is configured to have a stage to carry out thermal annealing (also called anneal heat treatment) after the first embodiment and the second embodiment Here, the anneal treatment means to carry out a heat treatment or a hydrothermal treatment under a constant temperature in a predetermined time. In the following, as an example there will be described a case where thermal annealing is carried out after bonding (only first stage pressing) of first embodiment.

In the present embodiment, the configuration of the resinous substrate 010, the configuration of the resinous film 020, the relation between the deflection temperatures under load and the boding temperature are the same as that of the first embodiment.

In the present embodiment, after bonding the resinous substrate 010 and resinous film 020 by heating and pressing, thermal annealing is carried out with respect to the resinous substrate 010 and resinous film 020.

Here, thermal annealing will be described. Occurrence of distortion of the resinous film 020 at the micro-channel 011 or the through hole 012 is considered to be a result of inflation of the resinous Elm 020 covering the micro-channel 011 or the through hole 012, or a result of the fact that the thickness of the resinous film is reduced by heating and as a result the area of the film is increased then the film is pushed into the micro-channel 011 and the through hole 012 by the increased amount of the area. Namely, in order to reduce or to eliminate the distortion of the resinous film 020, the resinous film 020 covering the micro-channel 011 and the through hole 012 has only to be contracted. It was confirmed by an experience that by heating up to around a glass transition temperature, the resinous film 020 contracts and the distortion of the resinous film 020 was reduced or eliminated. Since conditions of the thermal annealing such as heating temperature and heating time differ in accordance with a physical property and a thickness of the resinous film 020, a width of the micro-channel, and a diameter of the through hole, the conditions have to be determined for each micro-channel chip.

As methods of heating, there are cited a method to put the micro-channel chip into a heated atmosphere using a constant temperature oven, a method to heat the micro-channel chip partially using a heated air blower, and a method that the resinous film 020 absorbs UV light to be heated using a UV radiation device without being limited to the methods thereof. Also, a longer heating time was effective to correct the distortion, however there are possibilities of the deterioration of the resin, the deformations of the micro-channel 011 and through hole 012, and the deformation of the resinous substrate 010 itself. Thus, the conditions have to be adjusted so that the deteriorations and the deformations do not occur.

In the present embodiment, as the thermal annealing the chip is stored in the constant temperature oven for one hour at a 90° C.

As described above, by carrying out thermal annealing after bonding the resinous substrate 010 and the resinous film 020, the distortion of the resinous film 020 can be reduced or eliminated.

Next, specific examples related to the third embodiment will be described with reference to FIG. 4. FIG. 4 is a table describing conditions and results of examples and comparison examples in a third embodiment Examples 6, 7 and 8 showing operation conditions and results in FIG. 4 are examples related to the third embodiment. A state before thermal annealing in FIG. 4 describes that to which state of the micro-channel chip in FIG. 3 thermal annealing was applied. Also the distortion and the variation of the distortion of the resinous film 020 before the thermal annealing in FIG. 3 are the same as the distortion and the variation of the distortion of the resinous film 020 in a state before thermal annealing described in the foregoing.

### Example 6

In the example 6, the thermal annealing was carried out with respect to the micro-channel chip manufactured in example 1 in FIG. 3, thus the deflection temperatures under load of the resinous substrate 010 and the resinous film 020, the bonding temperature T, the pressing force P and the bonding time are the same as that in example 1.

Results of the present example will be described. The distortion of the resinous film 020 after the thermal annealing in the present example is 0.023. The above result shows that the distortion of the resinous film 020 was greatly reduced compared to the distortion of the resinous film 020 before thermal annealing of 0.045. Also, the variation of the distortion of the resinous film 020 after the thermal annealing in the present example was 0.02. The above result shows the variation of the distortion of the resinous film 020 after the thermal annealing is greatly reduced compared to the variation of the distortion of the resinous film 020 before the thermal annealing of 0.035.

### Example 7

In the example 7, the thermal annealing was applied to the micro-channel chip manufactured in the example 2 in FIG. 3, thus the deflection temperatures under load of the resinous substrate 010 and the resinous film 020, the bonding temperature T, the pressing force P and the bonding time are the same as that in example 2.

Results of the present example will be described. The distortion of the resinous film 020 after thermal annealing in the present example is 0.028. The above result shows that the distortion of the resinous film 020 was greatly reduced compared to the distortion of the resinous film 020 of 0.05 before thermal annealing. Also, the variation of the distortion of the resinous film 020 after thermal annealing in the present example was 0.03. The above result shows the variation of the distortion of the resinous film 020 after the thermal annealing is greatly reduced compared to the variation of the distortion of the resinous film 020 of 0.042 before the thermal annealing.

### Example 8

In the example 8, thermal annealing was applied to the micro-channel chip manufactured in the example 3 in FIG. 3, thus the deflection temperatures under load of the resinous substrate 010 and the resinous film 020, the bonding temperature T, the pressing force P and the bonding time are the same as that in example 3.

Results of the present example will be described. The distortion of the resinous film 020 after the thermal annealing in the present example was 0.035. The above result shows that the distortion of the resinous film 020 greatly reduced compared to the distortion of the resinous film 020 of 0.07 before thermal annealing. Also, the variation of the distortion of the resinous film 020 after thermal annealing in the present example was 0.035. The above result shows the variation of the distortion of the resinous film 020 after thermal annealing is greatly reduced compared to the variation of the distortion of the resinous film 020 of 0.045 before the thermal annealing.

### Example 12

In the comparison example 12, the thermal annealing was applied to the micro-channel chip manufactured in the comparison example 5 in FIG. 3, thus the deflection temperatures under load of the resinous substrate 010 and the resinous film 020, the bonding temperature T, the pressing force P and the bonding time are the same as that in the comparison example 5. Here, the reason why the thermal annealing was applied to the chip manufactured in the comparison example 5 is to reduce the distortion and the variation of the distortion of the resinous film 020 by applying the thermal annealing to the micro-channel chip having a problem in the distortion and the variation of the distortion of the resinous film 020 and no problems in other results, and to judge whether the same evaluation as that of the example corresponding to the present embodiment can be obtained or not.

Results of the present comparison example will be described. The distortion of the resinous film 020 after the thermal annealing in the present comparison example is 0.2. In the above result, the distortion was greatly reduced compared to the distortion of the resinous film 020 of 0.5 before the ⁻thermal annealing. However, the above value does not fall with in the range of 0≦t/d<0.1, and is large compared to the other examples, thus the reproducibility as the micro-channel chip is low. Also, the variation of the distortion of the resinous film 020 after the thermal annealing in the present example was 0.3. The above result shows that the variation of the distortion was greatly reduced compared to the variation of the distortion of the resinous film 020 of 0.45 before the thermal annealing. However, even with the above value, considerable degree of the variation of the distortion occurs compared to the other examples and the reproducibility as the micro-channel chip is deteriorated.

As described in the foregoing, according to the manufacturing method of the micro-channel chip related to the present embodiment, compared to the micro-channel chip before applying the thermal annealing, by applying the thermal annealing the distortion and the variation of the distortion can be reduced. Whereby, a micro-channel chip having a higher reproducibility can be manufactured.

### DESCRIPTION OF SYMBOLS

010 Resinous substrate

011 Micro-channel

012 Through hole

020 Resinous film

1. A micro-channel chip manufacturing method to bond a resinous film onto a surface of a resinous substrate on which a channel groove is formed, wherein a deflection temperature under load of the resinous substrate Ts (° C.) and a deflection temperature under load of the resinous film Tf (° C.) satisfy Ts>Tf, comprising a step of:
pressing the resinous film onto the resinous substrate with a pressure in the rage of 10 kgf/cm²-60 kgf/cm² under a bonding temperature of T (° C.) which satisfies Tf−5 (° C.)<T<Tf+5 (° C.).

2. The micro-channel chip manufacturing method of claim 1, wherein the step of pressing comprises:
a first pressing step to press the resinous film onto the resinous substrate with a pressure of more than 10 kgf/cm² and not more than 60 kgf/cm², and a second pressing step to press the resinous film onto the resinous substrate with a pressure smaller than the that of the first pressing step.

3. The micro-channel chip manufacturing method of claim 1, wherein the step of pressing comprises:
a first pressing step to press the resinous film onto the resinous substrate with a pressure of more than 30 kgf/cm² and not more than 60 kgf/cm², and
a second pressing step to press the resinous film onto the resinous substrate with a pressure in the rage of 10 kgf/cm²-30 kgf/cm²

4. The micro-channel chip manufacturing method of claim 2, wherein a pressing time of the fist pressing step is shorter than a pressing time of the second pressing step.

5. The micro-channel chip manufacturing method of claim 1, further comprising a step of applying thermal annealing to the resinous substrate and the resinous film before the step of pressing.

6. A micro-channel chip manufactured by the micro-channel chip manufacturing method of claim 1.

7. The micro-channel chip manufacturing method of claim 3, wherein a pressing time of the first pressing step is shorter than a pressing time of the second pressing step.
